(19) United States
(12) Patent Application Publication
(10) Pub. No.: US 2024/0389475 A1
(43) Pub. Date: Nov. 21, 2024

(54) MAKING A QUANTUM DEVICE WITH AN EMBEDDING JOSEPHSON JUNCTION

(71) Applicant: COMMISSARIAT À L'ÉNERGIE ATOMIQUE ET AUX ÉNERGIES ALTERNATIVES, Paris (FR)

(72) Inventors: Maxime MOULIN, Grenoble (FR); Mikael CASSE, Grenoble (FR); Frédéric GAILLARD, Grenoble (FR); Yves MORAND, Grenoble (FR)

(21) Appl. No.: 18/543,338

(22) Filed: Dec. 18, 2023

(30) Foreign Application Priority Data
Dec. 20, 2022 (FR) 2213899

(51) Int. Cl. H10N 60/01; H10N 60/12; H10N 60/80

(52) U.S. Cl. CPC H10N 60/0912; H10N 60/12; H10N 60/805

(57) ABSTRACT

Making a quantum device structure comprising: a substrate (10) provided with a crystalline silicon surface layer (102), a Josephson junction (160) formed by a first metal portion (132), a superconducting material (134), coated with an insulating zone (145), the insulating zone itself being coated with a second metal portion (152) of a superconducting material (134) and embedding the insulating zone (145) and the first metal portion (132), the first metal portion (132) and the second metal portion (152) being arranged on and in contact with a so-called “protective” layer (116) arranged on or in the substrate (10).

### DESCRIPTION OF INVENTION

### Technical Field and Prior Art

This application is directed to the field of quantum devices provided with at least one structure including a Josephson junction associated with a resonator, and with a method for manufacturing such a structure.

Resonators, in particular superconducting resonators, are components for reading spin states of quantum devices implementing quantum bits commonly referred to as “qubits” or “Qbits”.

A resonator of a quantum device is typically in the form of at least one microwave transmission line designed to be the locus of resonant oscillations under some particular conditions.

Quantum computation require low-loss resonator operations.

Quantum devices with qubits formed via Josephson junctions coupled to a superconducting resonator and in which quantum information can be exchanged via a photon have appeared.

Document: “Path toward manufacturable superconducting qubits with relaxation times exceeding 0.1 ms”, by Verjauw et al, npj Quantum Information volume 8, Article number: 93 (2022) provides for making a quantum device with a Josephson junction having a particular arrangement and which is implemented on a substrate compatible with the integration of components in CMOS (Complementary Metal Oxide Semiconductor) technology. Making the Josephson junction comprises depositing a superconducting material such as aluminium onto a substrate and then structuring this material.

This making can resort to using etching methods, which tend to introduce defects into the substrate on which the junction is made.

An argon ion beam milling method can in particular be used especially to remove a native oxide layer that forms on thin aluminium layers as a result of their exposure to the atmosphere between two lithographic steps. The aim is generally to avoid such oxide layers, which can prove to be harmful to the resonator.

This and other dry etching steps can lead to degradation in the surface layer of the substrate, which can limit quantum coherence time as well as quality factor of resonators formed thereon.

One way of improving performance of such devices when they are made on a silicon substrate and of avoiding detrimental consequences related to cleaning and/or etching methods is, once the resonator structure has been made, to surface etch the silicon substrate in a region facing the Josephson junction(s) and the resonator.

This type of etching needs to be controlled, especially in the presence of charges, to ensure performance of the Josephson junction. In addition, this type of etching poses a problem, especially when the structure is to be co-integrated with components in the surface layer of the substrate.

The problem arises of making a new quantum circuit device which is improved with regard to at least one of the drawbacks mentioned above.

### DISCLOSURE OF THE INVENTION

It is therefore a purpose of the present invention to provide a Josephson junction quantum device structure comprising:
a substrate provided with a surface layer of a crystalline semiconductor material, in particular crystalline silicon,
at least one Josephson junction, formed by at least one first metal portion, of a superconducting material, coated with an insulating zone, said insulating zone itself being coated with a second metal portion of a superconducting material and the second metal portion covering said insulating zone and said first metal portion,
the first metal portion and the second metal portion being disposed on and in contact with a so-called “protective” layer arranged on the substrate or belonging to the substrate, said protective layer being a charge-trapping layer also referred as “trap rich layer”.

Such an arrangement avoids the presence of crystalline defects in the crystalline surface semiconductor layer or ensures that any defects in the protective or trap rich layer are not detrimental to the crystalline surface semiconductor layer and to the operation of the device.

The Josephson junction is typically coupled or connected to a resonator. With an arrangement as defined above, the quality factor of the resonator is improved in this case.

The crystalline semiconductor layer is typically a silicon layer.

Advantageously, the trap rich layer is a semiconductor layer, in particular of hydrogenated amorphous silicon (aSi:H) or polysilicon or a layer of dielectric material, in particular silicon nitride.

An arrangement as defined above can advantageously make it possible to provide a surface layer of the substrate of a low resistivity crystalline semiconductor material.

By “low” resistivity, it is meant a resistivity of less than 50 Ω·cm and typically between 1 Ω·cm and 20 Ω·cm, in particular between 10 Ω·cm and 20 Ω·cm.

The first metal portion and the second metal portion are of a given superconducting material, which may in particular be aluminium.

According to one implementation possibility, the first metal portion is arranged on and in contact with a first metal track while the second metal portion is arranged on and in contact with a second metal track, the first metal track and the second metal track being of a different superconducting material from said given superconducting material, which different superconducting material may in particular be Niobium.

The trap rich layer can be disposed on the surface layer, the trap rich layer being of amorphous semiconductor material or polycrystalline material or a layer of dielectric material such as silicon nitride.

Advantageously, the protective layer entirely extends in contact with the surface layer of the substrate.

The first metal track or the second metal track can be connected or coupled to a resonator.

Preferably, the first metal track and the second metal track are disposed facing said protective layer or trap rich layer.

According to one alternative embodiment, the trap rich layer may be provided in a semiconducting pedestal of the substrate, the substrate being a semiconductor-on-insulator substrate provided with an insulating layer arranged between the semiconducting pedestal and the surface layer of a crystalline semiconductor material, the insulating layer and the surface layer of crystalline semiconductor material not extending facing said Josephson junction.

According to another aspect, the present invention relates to a method for manufacturing a quantum device as defined above.

More particularly, according to a first implementation possibility, the present invention relates to a method for manufacturing a structure as defined above and comprising, in this order, the following steps:
providing the substrate provided with the surface layer of crystalline semiconductor material, and then
depositing the protective or trap rich layer onto said surface layer, and then
making, on said protective layer, the first metal portion, and then the insulating zone on the first metal portion, and then the second metal portion on the insulating zone.

Advantageously, the insulating zone can be formed by oxidising the first metal portion.

According to one implementation possibility, the method can comprise in this order, after depositing the protective layer and prior to forming the first metal portion: forming a first metal track and a second metal track on said protective layer by depositing and then etching a first metal layer of a given superconducting material.

According to a second implementation possibility, the present invention relates to a method for manufacturing a structure as defined above and wherein the substrate is a semiconductor on insulator provided with a semiconducting pedestal provided with a trap rich layer, an insulating layer arranged on the trap rich layer and disposed between the semiconducting pedestal and the surface layer of crystalline semiconductor material, the method comprising the steps of:
removing the surface layer and the insulating layer in a localised region of the substrate, so as to reveal the trap rich layer, and then
making, in said localised zone of the substrate, the first metal portion on the trap rich layer, and then the insulating zone on the first metal portion, and then the second metal portion on the insulating zone.

### BRIEF DESCRIPTION OF THE DRAWINGS

The present invention will be better understood upon reading the description of exemplary embodiments given, by way of example only and in no way limiting, with reference to the appended drawings in which:

FIGS. 1A, 1B, 1C, 1D, 1E, 1F, 1G, 1H, 1I illustrate an exemplary embodiment of a quantum device having a structure formed by a Josephson junction coupled to a resonator and in which a protective layer is interposed between the structure and a surface layer of crystalline semiconductor material of a substrate.

FIGS. 2A-2B illustrate one particular example of making an embedding Josephson junction.

FIG. 3 illustrates one alternative embodiment in which the protective layer is a dielectric layer, in particular of the pre-metal type.

FIG. 4 illustrates one alternative embodiment in which the junction is made on the trap layer of a semiconductor-on-insulator substrate provided with a trap rich layer.

Identical, similar or equivalent parts of the different figures bear the same numerical references so as to facilitate switching from one figure to another.

The different parts represented in the figures are not necessarily represented according to a uniform scale, to make the figures more legible.

### DETAILED DESCRIPTION OF PARTICULAR EMBODIMENTS

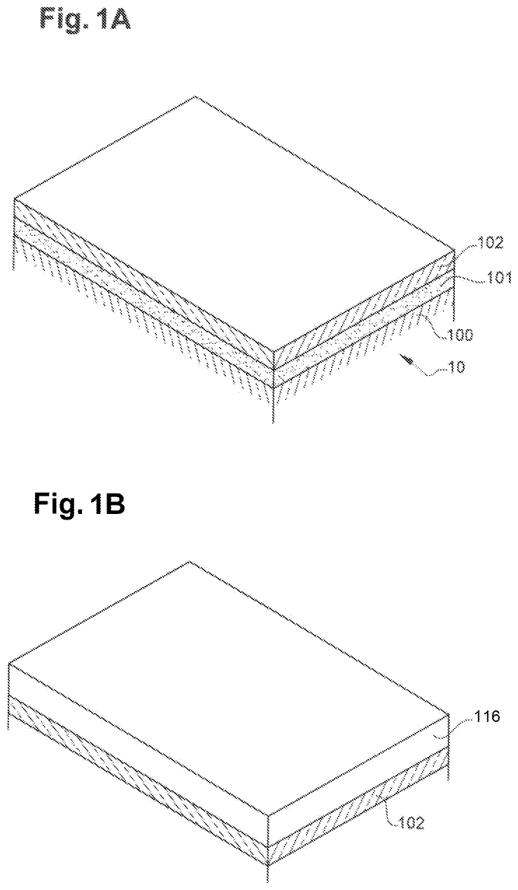

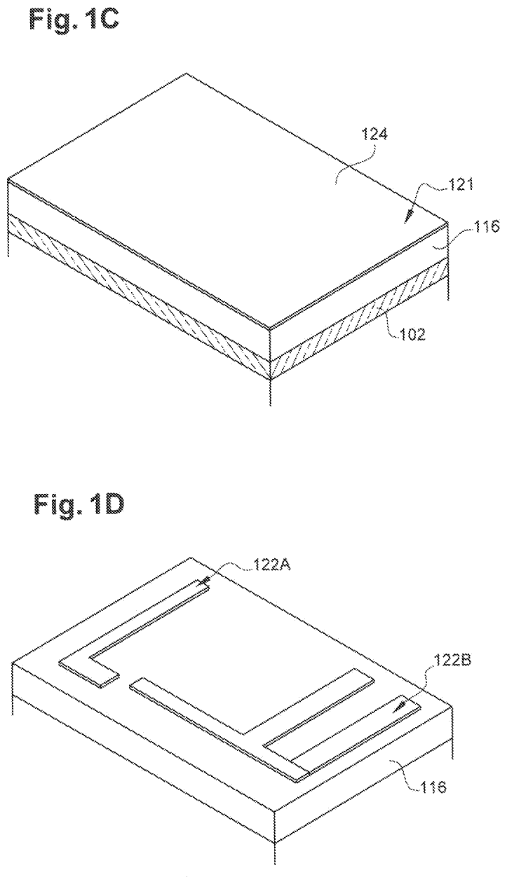

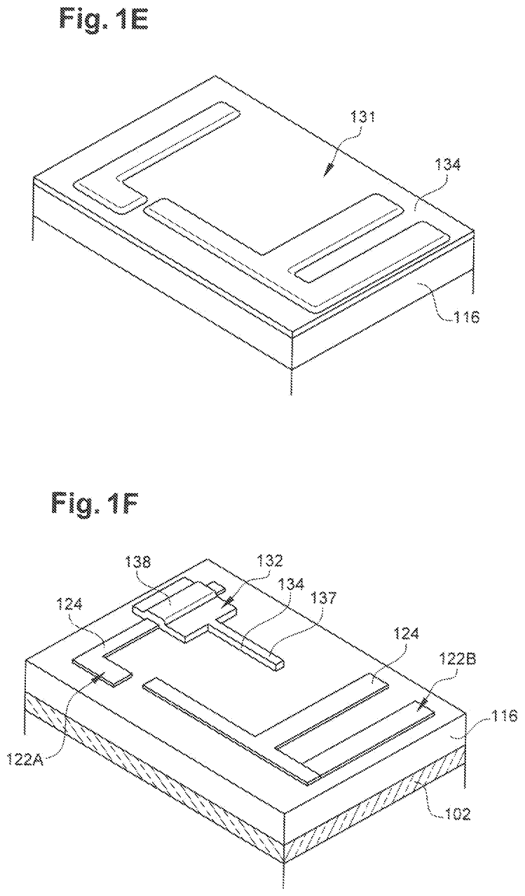

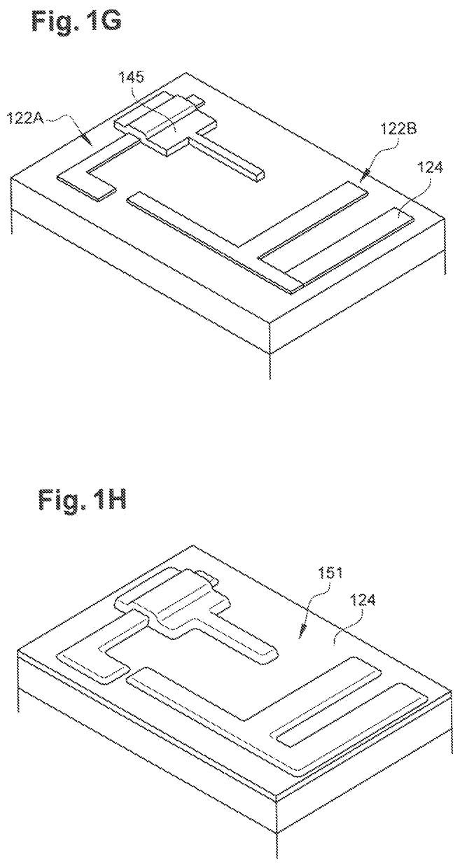

FIG. 1A will be first referred to, which shows a cross-section view of an example of a starting substrate for implementing a quantum device, in particular with spin Qbits, and provided with at least one Josephson junction coupled or connected to a resonator.

The substrate 10 is provided with a semiconductor surface layer 102 of a crystalline semiconductor material, in particular crystalline silicon. Advantageously, the surface layer 102 may here be a layer of a crystalline semiconductor material of low resistivity, that is having resistivity less than 50 Ω·cm and typically between 1 Ω·cm and 20 Ω·cm.

According to one implementation possibility and as illustrated in the exemplary embodiment in FIG. 1A, the substrate 10 may be of the semiconductor-on-insulator, in particular SOI (“Silicon On Insulator”), type and in this case includes a semiconducting pedestal 100, a buried insulating layer 101, typically called BOX (“Buried Oxide”) disposed on the semiconducting pedestal 100 and located between the semiconductor surface layer 102 and the semiconducting pedestal 100. The surface layer 102 can be provided with a thickness of, for example, between 10 nm and 10 μm, advantageously between 50 nm and 200 nm.

According to a particular step of the method, the substrate 10 is coated here (FIG. 1B) with a so-called “protective” layer 116. The material of this layer 116 can preferably be chosen so that, at the operating frequency of the resonator, the layer 116 has a low loss angle δ_{intrinsic} so that δ_{intrinsic}×10⁶ is between 0.1 and 1000. The operating frequency of the resonator may be between 1 and 10 GHZ, for example, advantageously between 4 and 8 GHz.

Advantageously, the protective layer 116 is a free trap rich layer. The protective layer 116 may be of an amorphous semiconductor material or polycrystalline material and/or porous semiconductor material.

According to one advantageous embodiment, the protective layer 116 can be of amorphous silicon, in particular hydrogenated amorphous silicon (a-SiH). The thickness of the protective layer 116 may, in this case, be between 10 nm and 10 μm, advantageously between 50 nm and 200 nm.

Alternatively, a protective layer 116 made of polysilicon and/or porous silicon may be provided. In this case, the thickness of this protective layer 116 may be between 10 nm and 10 μm, advantageously between 50 nm and 200 nm.

According to another exemplary embodiment, the trap rich layer 116 may be an insulator, for example a pre-metal insulator (PMD) such as silicon nitride (SixNy with x≠0 and y≠0). The thickness of this layer can in this case be provided between 10 nm and 10 μm for example, advantageously between 50 nm and 200 nm.

In this particular exemplary embodiment, the protective layer 116 is advantageously full-plate deposited and may cover the surface semiconductor layer 102 entirely. Subsequently, the protective layer 116 is advantageously preserved without the need for any subsequent etching of this layer 116.

A metal layer 121 of a first superconducting material 124, in particular Niobium (Nb) or Tantalum nitride (TaN), is then formed (FIG. 1C) on the support layer 116. Alternatively, other superconducting materials may be used, for example a superconductor selected from the following: TIN, NbTiN, NbN, AlOx, InOx, heavily doped or degenerated silicon, that is with a concentration greater than 10¹⁹ dopants/cm³, Tungsten, or cobalt silicide (CoSi₂).

A Niobium metal layer 121 with a thickness of between 1 nm and 1000 nm, for example in the order of 150 nm, may in particular be provided.

Etching (FIG. 1D) is the performed in the metal layer 121 to form metal tracks, in particular a first metal track 122A and a second metal track 122B.

Typically, etching is dry etching, in particular using a plasma and carried out through masking (not represented). Dry etching using a plasma can for example be implemented.

One of these tracks 122A, 122B, may be connected or coupled to a resonator, for example in the form of a microwave transmission line or one or more waveguides, designed to be the locus of resonant oscillations and which may also be formed in the metal layer 121.

A metal layer 131 of a second superconducting material 134, here different from the first superconducting material 124, and which may be easier to shape than the first superconducting material 124 is then deposited (FIG. 1E). The second superconducting material 134 may be, for example, aluminium (Al). Alternatively, other superconducting materials may be used, for example a superconductor selected from the following: TiN, TaN, NbTiN, NbN, AlOx, InOx, heavily doped silicon, Tungsten, or cobalt silicide (CoSi₂).

An aluminium metal layer 131 with a thickness of between 1 nm and 70 nm, in particular between 1 and 10 nm, may be in particular provided.

Etching (FIG. 1F) is then made in the metal layer 131 so as to form one or more metal portions, in particular at least one first metal portion 132 arranged on one of the metal tracks 122A, 122B, for example on the previously formed first track 122A. Dry etching using a plasma or wet etching using a chlorine solution BCl₃, for example, can be used.

The first metal portion 132 is here disposed so as to overlap part of the conductive track 122A and thus extends both over an upper face of the conductive track 122A and over its side faces. In the particular exemplary embodiment illustrated in FIG. 1F, the metal portion 132 is formed by a region 138 which embeds the track 122A and an end region 137 as an extension of this region 138, for example in the form of a bar, and which is narrowed relative to the region 138.

An insulating zone 145 is then formed on the metal portion 132. The exemplary embodiment illustrated in FIG. 1G provides in particular for the formation of this insulating zone 145 by oxidising the superconducting material 134, in this example aluminium. Oxidation can be carried out, for example, at a temperature in the order of 300° C. and under an atmosphere in the order of 1.33 Pa. Oxidising the material 134, in particular aluminium, of the metal portion 132 is preferably carried out while preserving the material 124 of the tracks 122A, 122B, in particular niobium. For this, a masking, which covers the tracks 122A, 122B but includes at least one opening revealing the metal portion 132 is typically provided.

A metal layer 151 of superconducting material, typically based on the second superconducting material 134, here different from the first superconducting material 124, and which may be aluminium (Al) is then deposited (FIG. 1G).

A metal Aluminium layer 151 with a thickness of, for example, between 2 nm and 70 nm, in particular between 10 nm and 30 nm, may in particular be provided.

Etching (FIG. 1H) is then made in the metal layer 151 so as to form one or more metal portions, in particular at least one metal portion 152 disposed on the second track 122B, of a previously formed superconducting material 124. Dry etching using a plasma or wet etching using, for example, a chlorine solution BCl₃ can be used.

The second metal portion 152 is here arranged so as to overlap part of the conductive track 122B and thus extends both over an upper face of the conductive track 122B and over its side faces. In the particular exemplary embodiment illustrated in FIG. 1I, the metal portion 152 is formed by a region 158 which overlaps the track 122B and an end region 157 as an extension of this region 158, for example in the form of a bar, and which is narrowed relative to the region 158. The second metal portion 152 embeds, here via its end region 157, part of the insulating zone 145 and of the first metal portion 132, in particular the end region 137 of this metal portion 132.

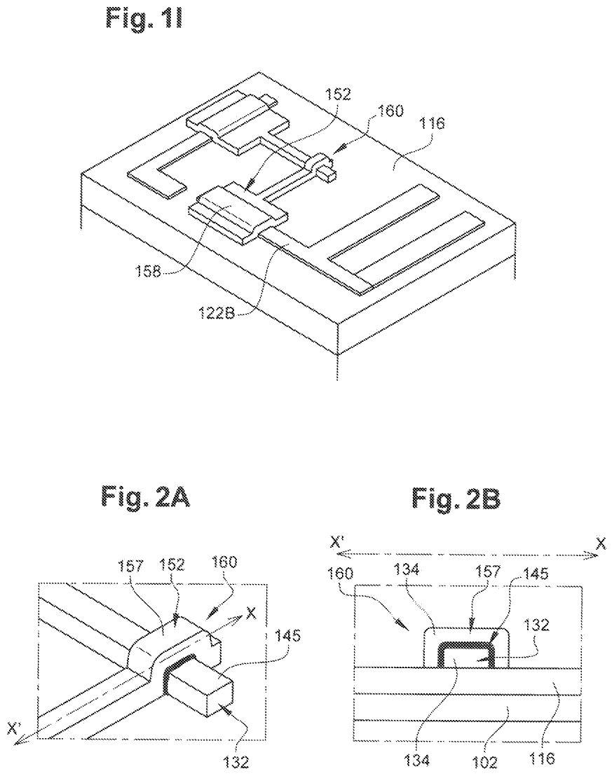

A so-called “embedding” or “bridging” Josephson junction structure 160 as illustrated in the perspective views of FIGS. 11 and 2A and the transverse cross-section view (the cross-section being taken along an axis X′X given in FIG. 2A) of FIG. 2B is thus made on the protective layer 116.

Making this junction, and in particular the metal portions 132, 152, can resort in particular to one or more Ar milling steps and/or one or more dry etching steps.

The protective layer 116 on which the tracks 122A, 122B and the metal portion 132 rest then makes it possible in particular to protect the surface semiconductor layer 102 of the substrate, which is of a crystalline semiconductor material, from such steps.

This Josephson junction 160 is made here without having to etch the protective layer 116 and without having to etch parts of the crystalline semiconductor material surface layer 102 disposed facing the Josephson junction.

This avoids introducing defects or impurities into the surface layer 102 during the manufacturing method and in particular during the etching and/or stripping steps implemented during this method, for example to form the metal tracks and/or portions 132, 152, 122A, 122B.

One advantage of implementing the intermediate layer 116, between the surface layer 102 of the substrate and the metal layers 131, 151 in which the coupled Josephson junction is formed, is that it makes it possible to obtain an improved coherence time for the qubits.

One advantage of implementing the intermediate layer 116, between the surface layer 102 of the substrate and the metal layer 121 in which the resonator is formed, is that it makes it possible to obtain a resonator with low parasitic losses and an improved quality factor.

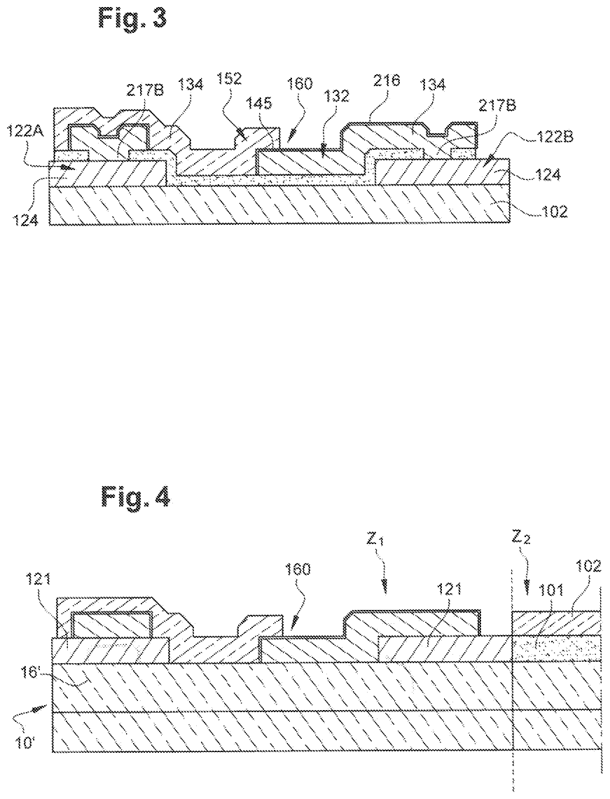

According to one alternative to the exemplary embodiment described above, a protective layer 216 as described above can be formed once the tracks 122A, 122B, of a superconducting material 124, for example Niobium, have been formed. However, such one alternative has the feature in comparison with the previous one of requiring, as illustrated in the structure of FIG. 3, of forming openings 217A, 217B in the protective layer 216. Such openings 217A, 217B typically formed after this layer 216 are made in order to be able to implement contact with the conducting portions 132, 152 of the Josephson junction 160. For such an alternative, the protective layer 216 may be, for example, a PMD insulating layer such as silicon nitride with a thickness, for example, in the order of 20 nm.

According to another alternative embodiment, the Josephson junction can be made on a trap rich layer this time belonging to a substrate 10′ and in particular a substrate of the semiconductor-on-insulator type and provided with a trap rich layer 16′. Such a layer 16′ belongs to the semiconducting pedestal located under the insulating layer 102. This trap rich layer 16′, which may be made of polycrystalline semiconductor material and in particular polysilicon, is typically disposed against and in contact with the insulating layer 101 of the substrate 10′.

To obtain such an arrangement, it can be contemplated in this case to remove the surface layer 102 from the substrate 10′ and the insulating layer 101 in a localised zone Z1 of the substrate 10′. On the other hand, the surface layer 102 of the substrate 10′ and the insulating layer 101 are preserved in other zones Z2 of the substrate 10′.

In the exemplary embodiment illustrated in FIG. 4, both the Josephson junction 160 and the metal layer 121 in which the resonator is made are formed in the localised zone Z1 of the substrate 10′ without a surface layer 102 or an insulating layer 101. In comparison with the method previously described in relation to FIGS. 1A-1I, such one alternative has the feature that it requires additional etching steps.

Thus, it is possible to start with a substrate 10′ of the semiconductor-on-insulator type and provided with a trap rich layer 16′, for example an RFeSI™ SOI substrate from the company SOITEC, and then to deposit masking onto a zone Z2 of the substrate to be protected and to etch the surface layer 12 and the BOX insulating layer 101 in a localised zone Z1 that is revealed and not covered with the masking.

The steps previously described in connection with FIGS. 1C-1I are then carried out in order to make the metal tracks 122A, 122B and the Josephson junction 160 on the trap rich layer 16′.

1. A Josephson junction quantum device structure comprising:
a substrate provided with a surface layer of a crystalline semiconductor material, in particular crystalline silicon,
at least one Josephson junction, formed by at least one first metal portion, of a superconducting material, coated with an insulating zone, said insulating zone itself being coated with a second metal portion of a superconducting material and the second metal portion covering said insulating zone and said first metal portion,
the first metal portion and the second metal portion being disposed on and in contact with a so-called “protective” layer arranged on the substrate or belonging to the substrate, said protective layer being a trap rich layer.

2. The structure according to claim 1, wherein the trap rich layer is of hydrogenated amorphous silicon (aSi:H) or polysilicon.

3. The structure according to claim 1, wherein the trap rich layer is based on silicon nitride.

4. The structure according to claim 1, wherein the surface layer of the substrate is of a crystalline semiconductor material with a low resistivity of between 10 Ω·cm and 20 Ω·cm.

5. The structure according to claim 1, wherein the protective layer entirely extends in contact with the surface layer of the substrate.

6. The structure according to claim 1, wherein the first metal portion and the second metal portion are of a given superconducting material, in particular aluminium, and wherein the first metal portion is arranged on and in contact with a first metal track, the second metal portion being arranged on and in contact with a second metal track, the first metal track and the second metal track being of a superconducting material different from said given superconducting material.

7. The quantum structure according to claim 1, the trap rich layer being disposed on said surface layer, the trap rich layer being of an amorphous semiconductor material or polycrystalline material or a layer of dielectric material such as silicon nitride.

8. The structure according to claim 1, the trap rich layer being provided in a semiconducting pedestal of the substrate, the substrate being a semiconductor-on-insulator substrate provided with an insulating layer arranged between the semiconducting pedestal and the surface layer of a crystalline semiconductor material, the insulating layer and the surface layer of crystalline semiconductor material not extending facing said Josephson junction.

9. A quantum device comprising a structure according to claim 1, wherein a resonator is coupled to the first metal track or to the second metal track, the resonator, the first metal track and the second metal track being disposed facing said protective layer (116).

10. A method for manufacturing a structure according to claim 1, comprising, in this order, the following steps:
providing the substrate with the surface layer of crystalline semiconductor material, and then
depositing the protective layer onto said surface layer, and then
making, on said protective layer, the first metal portion, and then the insulating zone on the first metal portion, and then the second metal portion on the insulating zone.

11. The method according to claim 10, wherein the insulating zone is formed by oxidising the first metal portion.

12. The method according to claim 10, comprising, in this order, after depositing the protective layer and prior to forming the first metal portion, forming a first metal track and a second metal track on said protective layer by depositing and then etching a first metal layer of a given superconducting material.

13. The method for manufacturing a structure according to claim 8, wherein the substrate is a semiconductor on insulator provided with a semiconducting pedestal provided with a trap rich layer, an insulating layer arranged on the trap rich layer and disposed between the semiconducting pedestal and the surface layer of a crystalline semiconductor material, the method comprising the steps of:
removing the surface layer and the insulating layer in a localised zone of the substrate, so as to reveal the trap rich layer, and then
making, in said localised zone of the substrate, the first metal portion on the trap rich layer, and then the insulating zone on the first metal portion, and then the second metal portion on the insulating zone.
